(19) United States
(12) Patent Application Publication
(10) Pub. No.: US 2022/0069113 A1
(43) Pub. Date: Mar. 3, 2022

(54) SEMICONDUCTOR STRUCTURES AND MANUFACTURING METHODS THEREOF

(71) Applicant: ENKRIS SEMICONDUCTOR, INC., Suzhou, Jiangsu (CN)

(72) Inventor: Kai CHENG, Suzhou, Jiangsu (CN)

(21) Appl. No.: 17/276,809

(22) PCT Filed: Nov. 26, 2019
(86) PCT No.: PCT/CN2019/120951

§ 371 Date: Mar. 16, 2021

(51) Int. Cl. H01L 29/778; H01L 29/20; H01L 29/66

(52) U.S. Cl. CPC H01L 29/7786; H01L 29/66462; H01L 29/2003

(57) ABSTRACT

The present disclosure provides semiconductor structures and methods of manufacturing the same. In the semiconductor structure, an in-situ insulating layer is formed on a heterojunction, a groove is provided in the in-situ insulating layer, and a transition layer is provided in the groove and on the in-situ insulating layer. A P-type semiconductor layer is provided on the transition layer in a gate region. The P-type semiconductor layer does not fully fill the groove.

### TECHNICAL FIELD

The present disclosure relates to the field of semiconductor technology, and in particular to semiconductor structures and manufacturing methods thereof.

### BACKGROUND

As a typical third-generation semiconductor material, Group III nitride semiconductor material is very suitable for manufacturing high temperature, high frequency and high power electronic devices due to its excellent characteristics of wide bandgap, resistance to high voltage, resistance to high temperature, high electron saturation speed and high electron drift velocity, being easy to form a heterostructure with high quality.

For example, as AlGaN/GaN heterojunction has strong spontaneous polarization and piezoelectric polarization, there is a high concentration of two-dimensional electron gas (2DEG) at the AlGaN/GaN interface, and as a result, the AlGaN/GaN heterojunction can be widely used in High Electron Mobility Transistors (HEMT) and other semiconductor structures.

Enhanced devices are widely used in the field of power electronics due to their normally-off characteristics. There are many ways to implement enhanced devices, for example, by providing a p-type semiconductor at a gate to deplete the two-dimensional electron gas.

### SUMMARY

However, the inventor of the present disclosure found that enhanced devices implemented by providing a p-type semiconductor at the gate has a low threshold voltage, and it is required to etch p-type semiconductor outside the gate region, which inevitably leads to etching loss.

To solve the above-mentioned problems, one aspect of the present disclosure provides a semiconductor structure, including:

a semiconductor substrate, a heterojunction and an in-situ insulating layer, which are arranged from bottom to top;

a groove passing through the in-situ insulating layer; a transition layer disposed in the groove and on the in-situ insulating layer;

a P-type semiconductor layer disposed on the transition layer in a gate region and not fully filling the groove.

In an optional embodiment of the present disclosure, the semiconductor structure further includes: a gate disposed on the P-type semiconductor layer; and a source and a drain disposed respectively on either side of the gate.

In an optional embodiment of the present disclosure, the heterojunction includes, from bottom to top, a channel layer and a barrier layer.

In an optional embodiment of the present disclosure, the heterojunction includes a GaN-based material.

In an optional embodiment of the present disclosure, material for the in-situ insulating layer includes at least one of SiN and SiAlN; and/or material for the transition layer includes at least one of AlN, SiAlN, and AlGaN.

In an optional embodiment of the present disclosure, the P-type semiconductor layer is further disposed in a non-gate region on the transition layer.

In an optional embodiment of the present disclosure, the heterojunction includes, from bottom to top, a channel layer and a barrier layer, and both the source and the drain contact the channel layer or the barrier layer.

Another aspect of the present disclosure provides a method of manufacturing semiconductor structure, including:

providing a semiconductor substrate, and forming a heterojunction on the semiconductor substrate;

forming an in-situ insulating layer on the heterojunction;

forming a groove which passes through the in-situ insulating layer;

forming a transition layer and a P-type semiconductor layer in the groove and on the in-situ insulating layer, wherein the P-type semiconductor layer does not fully fill the groove.

In an optional embodiment of the present disclosure, the method further includes: forming a gate in a gate region on the p-type semiconductor layer; and forming a source and a drain respectively on either side of the gate.

In an optional embodiment of the present disclosure, the heterojunction includes, from bottom to top, a channel layer and a barrier layer.

In an optional embodiment of the present disclosure, the heterojunction includes a GaN-based material.

In an optional embodiment of the present disclosure, material for the in-situ insulating layer includes at least one of SiN and SiAlN; and/or material for the transition layer includes at least one of AlN, SiAlN, and AlGaN.

In an optional embodiment of the present disclosure, the method further includes patterning the P-type semiconductor layer to remain a portion of the P-type semiconductor layer in the gate region.

In an optional embodiment of the present disclosure, the heterojunction includes, from bottom to top, a channel layer and a barrier layer, and both the source and the drain contact the channel layer or the barrier layer.

Compared with the prior art, the present disclosure may produce following beneficial effects:

1) In the semiconductor structure of the present disclosure, the in-situ insulating layer is formed on the heterojunction, and a groove is provided in the in-situ insulating layer, a transition layer is provided in the groove and on the in-situ insulating layer. The in-situ insulating layer facilitates to form the P-type semiconductor layer outside the groove during the process. The in-situ insulating layer and the transition layer can reduce a gate leakage current leaking from a channel to the gate, so a thickness of the barrier layer of the heterojunction can be relatively small, which can increase the threshold voltage. In addition, due to the arrangement of the in-situ insulating layer, the square resistance can be reduced, concentration of the two-dimensional electron gas may be increased, thereby improving ability of the gate to control the channel, and increasing the working current.

The arrangement of the transition layer can, on one hand, prevent selective growth of the P-type semiconductor on the in-situ insulating layer, thereby improving the quality of the P-type semiconductor layer, and it can further, on the other hand, prevent atoms (such as Si atoms) in the in-situ insulating layer from being diffused into the P-type semiconductor layer which affects the P-type semiconductor layer.

2) In optional embodiments of the present disclosure, the heterojunction includes, from bottom to top, a channel layer and a barrier layer. Specifically, a) there are one channel layer and one barrier layer; orb) there are a plurality of channel layers and a plurality of barrier layers which are alternately arranged; or c) there are one channel layer and two or more than two barrier layers, thereby meeting different functional requirements.

3) In optional embodiments of the present disclosure, the heterojunction includes GaN-based materials. The GaN-based material may include any one or any combination of GaN, AlGaN, and AlInGaN. The semiconductor structure of the present disclosure has strong compatibility with existing HEMT devices.

4) In optional embodiments of the present disclosure, the P-type semiconductor layer includes a GaN-based material. Material for the transition layer includes at least one of AlN, STAIN, and AlGaN. The GaN-based material may include any one or any combination of GaN, AlGaN, and AlInGaN. The transition layer is formed through an in-situ growth process, which can improve the quality of the subsequently formed P-type semiconductor layer.

5) In optional embodiments of the present disclosure, the P-type semiconductor layer is further disposed in a non-gate region on the transition layer. In other words, the P-type semiconductor layer on the transition layer may be patterned to remain only a portion of the P-type semiconductor layer in the gate region, for depleting excess two-dimensional electron gas under the gate. Due to the in-situ insulating layer and the transition layer, a portion of the P-type semiconductor layer in the non-gate region may not be patterned, such that portions of P-type semiconductor layer in the gate region and in the non-gate region are remained in the semiconductor structure.

6) In optional embodiments of the present disclosure, both the source and the drain contact the channel layer or the barrier layer so as to meet the requirements of different semiconductor structures.

### BRIEF DESCRIPTION OF THE FIGURES

FIG. 1 illustrates a schematic structural view of a semiconductor structure according to a first embodiment of the present disclosure;

FIG. 2 illustrates a flowchart of a method of manufacturing semiconductor structure according to the first embodiment of the present disclosure;

FIG. 3 to FIG. 5 illustrate schematic views of intermediate structures corresponding to the processes of FIG. 2;

FIG. 6 illustrates a schematic structural view of a semiconductor structure according to a second embodiment of the present disclosure;

FIG. 7 illustrates a schematic structural view of a semiconductor structure according to a third embodiment of the present disclosure;

FIG. 8 illustrates a flowchart of a method of manufacturing the semiconductor structure according to the third embodiment of the present disclosure;

FIG. 9 illustrates a schematic structural view of a semiconductor structure according to a fourth embodiment of the present disclosure;

FIG. 10 illustrates a flowchart of a method of manufacturing the semiconductor structure according to the fourth embodiment of the present disclosure.

To facilitate the understanding of the present disclosure, all reference signs appearing in the present disclosure are listed below:

| | |
|---|---|
| Semiconductor structure | 1, 2, 3, 4 |
| Semiconductor substrate | 10 |
| Heteroj unction | 11 |
| In-situ insulating layer | 12 |
| Groove | 13 |
| Transition layer | 14 |
| P-type semiconductor layer | 15a |
| Gate | 15b |
| Source | 16 |
| Drain | 17 |
| Channel layer | 11a |
| Barrier layer | 11b |

### DETAILED DESCRIPTION

In order to make the above-mentioned objectives, features and advantages of the present disclosure easier to be understood, specific embodiments of the present disclosure will be described in detail below with reference to the accompanying drawings.

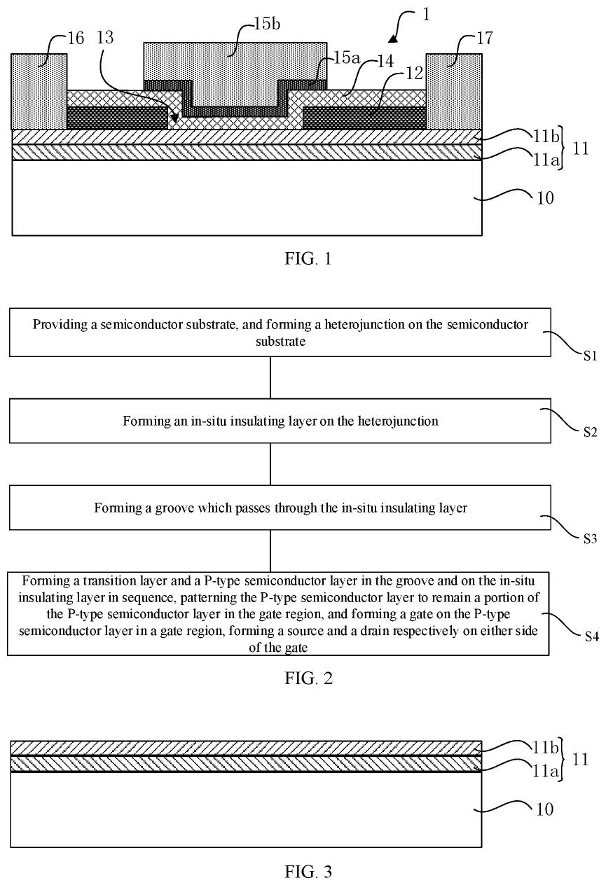

FIG. 1 illustrates a schematic structural view of a semiconductor structure according to a first embodiment of the present disclosure.

Referring to FIG. 1, the semiconductor structure 1 includes:

a semiconductor substrate 10, a heterojunction 11 and an in-situ insulating layer 12, which are arranged from bottom to top;

a groove 13, passing through the in-situ insulating layer 12; a transition layer 14 disposed in the groove 13 and on the in-situ insulating layer 12;

a P-type semiconductor layer 15a and a gate 15b, disposed in a gate region on the transition layer 14, and a source 16 and a drain 17 disposed respectively on either side of the gate 15b.

The semiconductor substrate 10 may be made of sapphire, silicon carbide, silicon, GaN or diamond.

The heterojunction 11 may include, from bottom to top, a channel layer 11a and a barrier layer 11b. Two-dimensional electron gas may be formed at an interface between the channel layer 11a and the barrier layer 11b. In an optional embodiment of the present disclosure, the channel layer 11a is an intrinsic GaN layer, and the barrier layer 11b is an N-type AlGaN layer. In other optional embodiments of the present disclosure, the combination of the channel layer 11a and the barrier layer 11b may further be GaN/AlN, GaN/InN, GaN/InAlGaN, GaAs/AlGaAs, GaN/InAlN or InN/InAlN. Further, in addition to the structure with one channel layer 11a and one barrier layer 11b as illustrated in FIG. 1, there may be a plurality of channel layers 11a and a plurality of barrier layers 11b which are alternately arranged; or there may be one channel layer 11a and two or more than two barrier layers 11b so as to form a multi-barrier structure.

There may further be a nucleation layer and a buffer layer (not shown) between the heterojunction 11 and the semiconductor substrate 10. Material for the nucleation layer may be, for example, AlN, AlGaN, etc., and material for the buffer layer may include at least one of AlN, GaN, AlGaN, and AlInGaN. The nucleation layer can mitigate problems of lattice mismatch or thermal mismatch between the epitaxially grown semiconductor layers such as the channel layer 11a of the heterojunction 11 and the semiconductor substrate 10, and the buffer layer may reduce dislocation density or defect concentration of the epitaxially grown semiconductor, thereby improving the crystal quality.

The in-situ insulating layer 12 is an insulating layer formed through an in-situ growth process. One of the functions of the in-situ insulating layer 12 is to electrically insulate the gate 15b from the barrier layer 11b outside the groove 13. The in-situ insulating layer 12 may further suppress the current collapse effect in the HEMT structure.

In an optional embodiment of the present disclosure, the in-situ insulating layer 12 has a single-layer structure, material for which may be one of SiN and SiAlN or a mixture thereof. In another optional embodiment of the present disclosure, the in-situ insulating layer 12 is a laminated structure, which can include, from bottom to top, a SiN layer and a SiAlN layer, a SiAlN layer and a SiN layer, or a SiN layer, a SiAlN layer and a SiN layer, etc.

The transition layer 14 may be formed through an in-situ growth process. In an optional embodiment of the present disclosure, the transition layer 14 has a single-layer structure, material for which may include one of AlN, SiAlN, and AlGaN or a mixture thereof. In another optional embodiment of the present disclosure, the transition layer 14 has a laminated structure, which includes at least two layers of an AlN layer, a SiAlN layer, and an AlGaN layer. The transition layer 14 of the above-mentioned material can solve the problem that the P-type GaN-based material cannot be grown on the in-situ insulating layer 12, so that the P-type semiconductor layer 15a can be formed outside the groove 13.

The P-type semiconductor layer 15a may be made of a GaN-based material, such as at least one of AlN, GaN, AlGaN, and AlInGaN, and the P-type doping ions may be magnesium ions to deplete the two-dimensional electron gas under the gate region to form an enhanced device.

As illustrated in FIG. 1, both the source 16 and the drain 17 contact the barrier layer 11b, and an ohmic contact is formed between the source 16 and the barrier layer 11b and between the drain 17 and the barrier layer 11b. And an ohmic contact is also formed between the gate 15b and the P-type semiconductor layer 15a. The source 16, the drain 17, and the gate 15b may be made of metal, doped polysilicon and other existing conductive materials.

In the above-mentioned semiconductor structure 1, the in-situ insulating layer 12 together with the transition layer 14 reduce a gate leakage current leaking from the channel to the gate 15b, so that a thickness of the barrier layer 11b of the heterojunction 11 may be relatively small, thereby reducing the threshold voltage. In addition, due to the arrangement of the in-situ insulating layer 12, a surface resistance can be reduced, and concentration of the two-dimensional electron gas can be increased, thereby improving ability of the gate to control the channel and increasing the working current.

The arrangement of the transition layer 14 can, on one hand, prevent the selective growth of the P-type semiconductor layer 15a on the in-situ insulating layer 12, thereby improving the quality of the P-type semiconductor layer; it can further, on the other hand, prevent atoms of the in-situ insulating layer 12 (for example, Si atoms) from being diffused into the P-type semiconductor layer and affecting the P-type semiconductor layer.

In order to verify the technical effect of the present disclosure, taking the barrier layer 11b with a thickness of 5 nm as an example, comparing a semiconductor structure with Al0.25GaN barrier layer of 5 nm/GaN channel layer with a semiconductor structure with an in-situ SiN layer of 5 nm/Al0.25GaN barrier layer of 5 nm/a GaN channel layer, it is found that a square resistance (surface resistance) between the source 16 and the drain 17 may be reduced from 2300Ω/□ to 325Ω/□, and concentration of the two-dimensional electron gas in the heterojunction 11 may be increased from 2.4E12/cm² to 1.03E13/cm².

In addition, in an existing HEMT structure with AlGaN barrier layer/GaN channel layer, the barrier layer 11b is required to have a thickness of 15 nm-25 nm so as to guarantee generation of two-dimensional electron gas of sufficient concentration. While in the present disclosure, in a case that the thickness of the barrier layer 11b ranges from 1 nm to 15 nm, two-dimensional electron gas of sufficient concentration may be generated. In an embodiment of the present disclosure, the thickness of the barrier layer 11b may be kept below 10 nm.

FIG. 2 illustrates a flowchart of a method of manufacturing a semiconductor structure according to the first embodiment of the present disclosure; FIG. 3 to FIG. 5 illustrate schematic views of intermediate structures corresponding to the flowchart of FIG. 2.

First, referring to step S1 of FIG. 2 and FIG. 3, a semiconductor substrate 10 is provided, and a heterojunction 11 is formed on the semiconductor substrate 10.

The semiconductor substrate 10 may be made of sapphire, silicon carbide, silicon, GaN or diamond.

The heterojunction 11 may include a channel layer 11a and a barrier layer 11b which are arranged in sequence from bottom to top. In an optional embodiment of the present disclosure, the channel layer 11a is an intrinsic GaN layer, and the barrier layer 11b is an N-type AlGaN layer. In other optional embodiments of the present disclosure, the combination of the channel layer 11a and the barrier layer 11b may further be GaN/AlN, GaN/InN, GaN/InAlGaN, GaAs/AlGaAs, GaN/InAlN or InN/InAlN. A process for forming the channel layer 11a and the barrier layer 11b may include: Atomic layer deposition (ALD), or Chemical Vapor Deposition (CVD), or molecular beam epitaxy (MBE), or Plasma Enhanced Chemical Vapor Deposition (PECVD), or Low Pressure Chemical Vapor Deposition (LPCVD), or Metal-Organic Chemical Vapor Deposition (MOCVD), or any combination thereof.

In addition to the structure as illustrated in FIG. 1 where there is one channel layer 11a and one barrier layer 11b, there may be a plurality of channel layers 11a and a plurality of barrier layers 11b which are alternately arranged; or there are one channel layer 11a and two or more than two barrier layers 11b to form a multi-barrier structure.

Before forming the heterojunction 11 on the semiconductor substrate 10, a nucleation layer and a buffer layer (not shown) may be formed firstly in sequence. Material for the nucleation layer may be, for example, AlN, or AlGaN, etc., and material for the buffer layer may include at least one of AlN, GaN, AlGaN, AlInGaN. The buffer layer may be formed through the same manner as the heterojunction 11. The nucleation layer may alleviate the problems of lattice mismatch or thermal mismatch between the epitaxially grown semiconductor layers, such as the channel layer 11a of the heterojunction 11, and the semiconductor substrate 10, and the buffer layer may reduce dislocation density or defect concentration of the epitaxially grown semiconductor, thereby improving the crystal quality.

Result of testing the square resistance (surface resistance) of the example structure illustrated in FIG. 3 shows that the square resistance is 2300Ω/□.

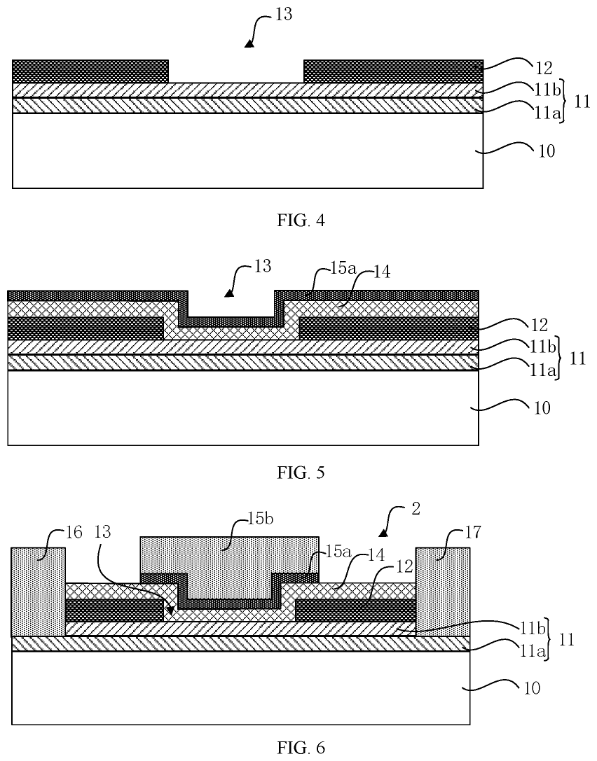

Next, referring to step S2 of FIG. 2 and FIG. 4, an in-situ insulating layer 12 is formed on the heterojunction 11.

The in-situ insulating layer 12 is an insulating layer formed via an in-situ growth process. In an optional embodiment of the present disclosure, the in-situ insulating layer 12 has a single-layer structure, material for which includes at least one of SiN and SiAlN. In another optional embodiment of the present disclosure, the in-situ insulating layer 12 has a laminated structure, which may include, from bottom to top, a SiN layer and a SiAlN layer, a SiAlN layer and a SiN layer, or a SiN layer, a SiAlN layer and a SiN layer, etc.

After that, referring to step S3 of FIG. 2 and FIG. 4, a groove 13 passing through the in-situ insulating layer 12 is formed.

The groove 13 may be formed through dry etching or wet etching. In an embodiment of the present disclosure, a patterned mask layer is first formed on the in-situ insulating layer 12. The mask layer may be a photoresist layer, which is patterned by a process of first exposing and then developing. The dry etching gas may be CF4, C3F8, and etc., and the wet etching solution may be hot phosphoric acid.

Result of testing the square resistance (surface resistance) of the example structure illustrated in FIG. 4 shows that the square resistance is 325Ω/□.

Next, referring to step S4 of FIG. 2 and FIG. 5, a transition layer 14 and a P-type semiconductor layer 15a are formed both in the groove 13 and on the in-situ insulating layer 12. Referring to FIG. 1, the P-type semiconductor layer 15a is patterned, and a portion of the P-type semiconductor layer 15a in the gate region is remained; a gate 15b is formed in the gate region on the P-type semiconductor layer 15a; and a source 16 and a drain 17 are formed respectively on either side of the gate 15b.

The transition layer 14 may be formed through an in-situ growth process. In an optional embodiment of the present disclosure, the transition layer 14 has a single-layer structure, material for which may include: one or a combination of AlN, SiAlN, and AlGaN. In another optional embodiment of the present disclosure, the transition layer 14 has a laminated structure, which may include at least two layers of an AlN layer, a SiAlN layer, and an AlGaN layer.

The P-type semiconductor layer 15a includes a GaN-based material, for example, at least one of GaN, AlGaN, and AlInGaN, and the P-type doping ions may be magnesium ions. Process for forming the P-type semiconductor layer 15a may be referred to the process for forming the channel layer 11a and the barrier layer 11b.

The P-type semiconductor layer 15a may be patterned through dry etching or wet etching. With respect to the scheme of patterning the P-type semiconductor layer 15a directly formed on the barrier layer 11b, the in-situ insulating layer 12 along with the transition layer 14 may prevent the barrier layer 11b from being damaged by over-etching during the patterning process.

The source 16, the drain 17, and the gate 15b may be made of existing conductive materials such as metal, doped polysilicon, etc., and correspondingly, may be formed by physical vapor deposition or chemical vapor deposition.

FIG. 6 illustrates a schematic structural view of a semiconductor structure according to a second embodiment of the present disclosure.

Referring to FIG. 6 and FIG. 1, the semiconductor structure 2 according to the second embodiment is substantially the same as the semiconductor structure 1 according to the first embodiment, except that both the source 16 and the drain 17 contact the channel layer 11a.

An ohmic contact is formed between the source 16 and the channel layer 11a, and between the drain 17 and the channel layer 11a.

Correspondingly, the method of manufacturing the semiconductor structure 2 according to the second embodiment is substantially the same as the method of manufacturing the semiconductor structure 1 according to the first embodiment, except that in step S4, upon forming the source 16 and the drain 17 respectively on either side of the gate 15b, a portion of the P-type semiconductor layer 15a, a portion of the transition layer 14, a portion of the in-situ insulating layer 12, and a portion of the barrier layer 11b in the source region and the drain region are removed, and the channel layer 11a is exposed.

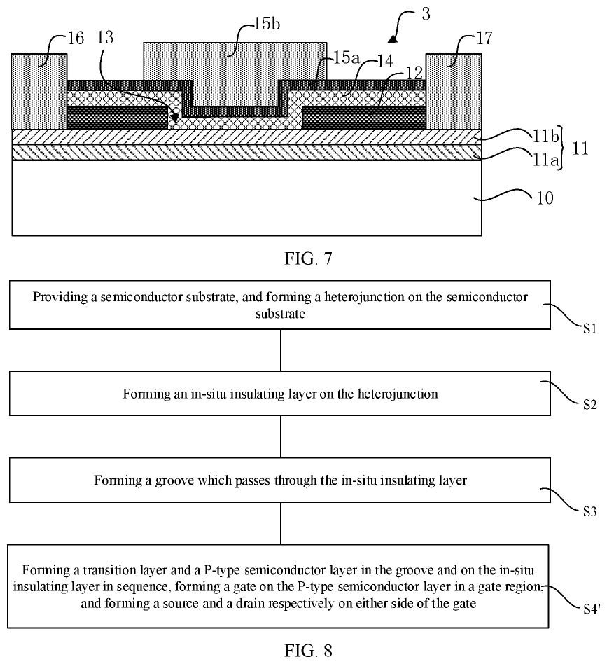

FIG. 7 illustrates a schematic structural view of a semiconductor structure according to a third embodiment of the present disclosure. FIG. 8 is a flowchart of a method of manufacturing the semiconductor structure according to the third embodiment of the present disclosure.

Referring to FIG. 7, FIG. 1 and FIG. 6, the semiconductor structure 3 according to the third embodiment is substantially the same as the semiconductor structure 1 according to the first embodiment and the semiconductor structure 2 according to the second embodiment. The only difference lies in that: the P-type semiconductor layer 15a is further disposed on the transition layer 14 in a non-gate region outside the gate region.

Correspondingly, referring to FIG. 8 and FIG. 2, a method of manufacturing the semiconductor structure 3 according to the third embodiment is substantially the same as the methods of manufacturing the semiconductor structure 1 according to the first embodiment and the semiconductor structure 2 according to the second embodiment, except that: in step S4′, patterning the P-type semiconductor layer 15a is omitted. In other words, step S4′ includes: forming a transition layer 14 and a P-type semiconductor layer 15a in sequence in the groove 13 and on the in-situ insulating layer 12; forming a gate 15b on a portion of the P-type semiconductor layer 15a in the gate region; and forming a source 16 and a drain 17 respectively on either side of the gate 15b.

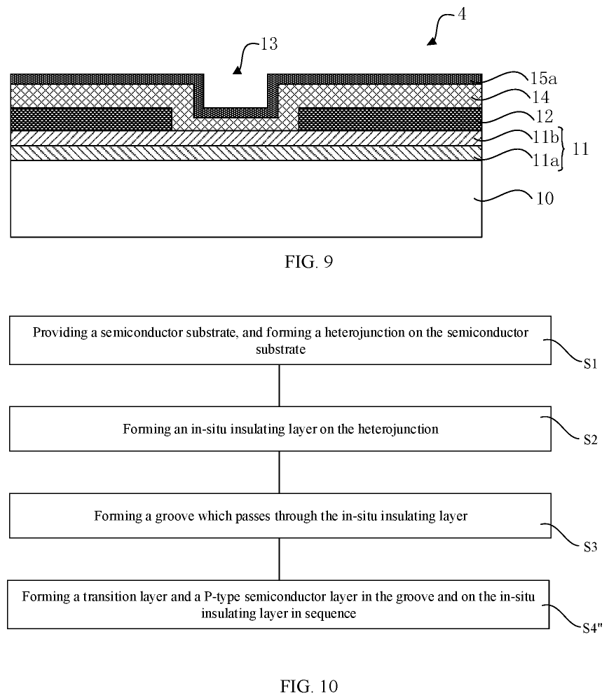

FIG. 9 illustrates a schematic structural view of a semiconductor structure according to a fourth embodiment of the present disclosure. FIG. 10 illustrates a flowchart of a method of manufacturing the semiconductor structure according to the fourth embodiment of the present disclosure. Referring to FIG. 9 and FIG. 1, the semiconductor structure 4 according to the fourth embodiment is substantially the same as the semiconductor structure 1 according to the first embodiment, except that the semiconductor structure 4 is an intermediate semiconductor structure, without a gate 15b, a source 16 and a drain 17.

Correspondingly, referring to FIG. 10 and FIG. 2, a method of manufacturing the semiconductor structure 4 according to the fourth embodiment is substantially the same as the method of manufacturing the semiconductor structure 1 according to the first embodiment, except that: in step S4″, forming the gate 15b, the source 16 and the drain 17 is omitted, and the P-type semiconductor layer 15a does not fully fill the groove 13.

The semiconductor structure 4 may further be manufactured and sold as a semi-finished product.

Although the present disclosure is disclosed as above, the present disclosure is not limited to that. One of ordinary skill in the art can make various changes and modifications without departing from the spirit and scope of the present disclosure. Therefore, the protection scope of the present disclosure is defined by the claims.

1. A semiconductor structure, comprising:
a semiconductor substrate (10), a heterojunction (11) and an in-situ insulating layer (12), which are arranged from bottom to top;
a groove (13), passing through the in-situ insulating layer (12);
a transition layer (14), disposed in the groove (13) and on the in-situ insulating layer (12); and
a P-type semiconductor layer (15a), disposed on the transition layer (14), wherein the P-type semiconductor layer (15a) does not fully fill the groove (13).

2. The semiconductor structure according to claim 1, further comprising:
a gate (15b), disposed on the P-type semiconductor layer (15a); and
a source (16) and a drain (17), disposed respectively on either side of the gate (15b).

3. The semiconductor structure according to claim 1, wherein the heterojunction (11) comprises, from bottom to top, a channel layer (11a) and a barrier layer (11b).

4. The semiconductor structure according to claim 1, wherein the heterojunction (11) comprises a GaN-based material.

5. The semiconductor structure according to claim 1, wherein material for the in-situ insulating layer (12) comprises at least one of SiN and SiAlN; and/or
material for the transition layer (14) comprises at least one of AlN, SiAlN, and AlGaN.

6. The semiconductor structure according to claim 1, wherein the P-type semiconductor layer (15a) is extended on the transition layer (14) to outside of the gate.

7. The semiconductor structure according to claim 2, wherein the heterojunction (11) comprises, from bottom to top, a channel layer (11a) and a barrier layer (11b), wherein both the source (16) and the drain (17) contact the channel layer (11a) or the barrier layer (11b).

8. A method of manufacturing semiconductor structure, comprising:
providing a semiconductor substrate (10);
forming a heterojunction (11) on the semiconductor substrate (10);
forming an in-situ insulating layer (12) on the heterojunction (11);
forming a groove (13) which passes through the in-situ insulating layer (12); and
forming both a transition layer (14) and a P-type semiconductor layer (15a) in the groove (13) and on the in-situ insulating layer (12), wherein the P-type semiconductor layer (15a) does not fully fill the groove (13).

9. The method according to claim 8, further comprising:
forming a gate (15b) on the p-type semiconductor layer (15a) in a gate region; and
forming a source (16) and a drain (17) respectively on either side of the gate (15b).

10. The method according to claim 8, wherein the heterojunction (11) comprises, from bottom to top, a channel layer (11a) and a barrier layer (11b).

11. The method according to claim 8, wherein the heterojunction (11) comprises a GaN-based material.

12. The method according to claim 8, wherein material for the in-situ insulating layer (12) comprises at least one of SiN and SiAlN; and/or
material for the transition layer (14) comprises at least one of AlN, SiAlN, and AlGaN.

13. The method according to claim 8, further comprising:
patterning the P-type semiconductor layer (15a) to remain a portion of the P-type semiconductor layer (15a) in the gate region.

14. The method according to claim 9,
wherein the heterojunction (11) comprises, from bottom to top, a channel layer (11a) and a barrier layer (11b),
wherein both the source (16) and the drain (17) contact the channel layer (11a) or the barrier layer (11b).

15. The semiconductor structure according to claim 2, wherein the heterojunction comprises a GaN-based material.

16. The semiconductor structure according to claim 2, wherein
material for the in-situ insulating layer comprises at least one of SiN and SiAlN; and/or
material for the transition layer comprises at least one of AlN, SiAlN, and AlGaN.

17. The method according to claim 9, wherein the heterojunction comprises a GaN-based material.

18. The method according to claim 9, wherein material for the in-situ insulating layer comprises at least one of SiN and SiAlN; and/or
material for the transition layer comprises at least one of AlN, SiAlN, and AlGaN.
